(19) United States
(12) Patent Application Publication
(10) Pub. No.: US 2022/0263332 A1
(43) Pub. Date: Aug. 18, 2022

(54) BATTERY CHARGING AND DISCHARGING APPARATUS AND METHOD

(71) Applicant: LG ENERGY SOLUTION, LTD., Seoul (KR)

(72) Inventor: Jeong Wan KIM, Daejeon (KR)

(73) Assignee: LG ENERGY SOLUTION, LTD., Seoul (KR)

(21) Appl. No.: 17/665,930

(22) Filed: Feb. 7, 2022

(30) Foreign Application Priority Data
Feb. 16, 2021 (KR) 10-2021-0020705

(51) Int. Cl. H02J 7/00; H01M 10/44

(52) U.S. Cl. CPC H02J 7/0071; H02J 7/0049; H01M 10/448; H02J 7/0068; H02J 7/005

(57) ABSTRACT

There is provided a portable battery charging and discharging apparatus connected to a battery to activate the battery, the battery charging and discharging apparatus including a power supply storing power discharged from the battery and supplying the power to the battery and a controller storing the power in the power supply by discharging the battery and charging the battery by continuously supplying the power stored in the power supply to the battery.

### CROSS REFERENCE TO RELATED APPLICATION

The present application claims priority to Korean Patent Application No. 10-2021-0020705, filed on Feb. 16, 2021, the entire contents of which is incorporated herein for all purposes by this reference.

### BACKGROUND OF THE INVENTION

### Field of the Invention

Embodiments disclosed herein relate to a battery charging and discharging apparatus and method.

### Description of the Related Art

Recently, research and development of secondary batteries have been actively performed. Herein, the secondary batteries, which are chargeable/dischargeable batteries, may include all of conventional nickel (Ni)/cadmium (Cd) batteries, Ni/metal hydride (MH) batteries, etc., and recent lithium-ion batteries. Among the secondary batteries, a lithium-ion battery has a much higher energy density than those of the conventional Ni/Cd batteries, Ni/MH batteries, etc. Moreover, the lithium-ion battery may be manufactured to be small and lightweight, such that the lithium-ion battery has been used as a power source of mobile devices. In addition, the lithium-ion battery is attracting attention as a next-generation energy storage medium as a usage range thereof is expanded to a power source of electric vehicles.

Furthermore, the secondary battery is generally used as a battery pack including a battery module where a plurality of battery cells are connected to one another in series and/or in parallel. The battery pack may be managed and controlled by a battery management system in terms of a state and an operation.

As representative devices using these battery cells typically, there may be an electric vehicle (EV) and an energy storage system (ESS). The batteries included in these devices are often discarded because of failing to satisfy an output condition, in spite of a lot of life left. Consequently, ways to reuse these batteries with new applications rather than disposing the batteries have been attempted. For example, such reusage applications may include an ESS grid, uninterruptible power supply system (UPS), a scooter, etc.

As such, it is necessary to classify a class of each battery cell for a variety of applications to reuse batteries. As a result, recently, an alternating current (AC) impedance measurement method that classifies a class of a battery in a short time has attracted attention, in which for AC impedance measurement, battery voltage check and management of an idle time after charge/discharge are important. In addition, a battery charger/discharger is used for AC impedance measurement, and the existing charger/discharger should be used with a chamber for loading a battery, occupying a lot of space.

### SUMMARY OF THE INVENTION

Embodiments disclosed herein aim to provide a battery charging and discharging apparatus and method, in which a battery is activated using a portable charging and discharging apparatus, thereby easily managing an idle time for alternating current (AC) impedance measurement of the battery and reducing a volume of the apparatus.

Technical problems of the embodiments disclosed herein are not limited to the aforementioned technical problems, and other unmentioned technical problems would be clearly understood by those of ordinary skill in the art from the following description.

A portable battery charging and discharging apparatus connected to a battery to activate the battery, according to an embodiment disclosed herein, may include a power supply storing power discharged from the battery and supplying the power to the battery and a controller storing the power in the power supply by discharging the battery and charging the battery by continuously supplying the power stored in the power supply to the battery.

According to an embodiment, the controller may automatically the battery at a preset time and then recharge the battery.

According to an embodiment, the preset time may be determined in consideration of a time at which the battery enters a rest period.

According to an embodiment, the controller may charge the battery such that a voltage of the battery reaches a reference voltage.

According to an embodiment, the reference voltage may be set to a voltage that enables alternating current (AC) impedance measurement of the battery.

According to an embodiment, a size of the battery charging and discharging apparatus may be determined according to a current magnitude and a capacity of the battery.

According to an embodiment, a power for charging and discharging the battery may have a value greater than or equal to a threshold value that enables a chemical reaction to be initiated in the battery.

According to an embodiment, the battery charging and discharging apparatus may be connected to a terminal of the battery through a cable.

A battery charging and discharging method using a portable battery charging and discharging apparatus connected to a battery to activate the battery, according to an embodiment disclosed herein includes discharging the battery, storing a power discharged from the battery, and charging the battery by continuously supplying the stored power to the battery.

According to an embodiment, the discharging of the battery may include automatically discharging the battery at a preset time.

According to an embodiment, the preset time of the battery charging and discharging method may be determined in consideration of a time at which the battery enters a rest period.

### BRIEF DESCRIPTION OF THE DRAWINGS

FIG. 1 is a block diagram showing a structure of a general battery pack;

FIG. 2 is a block diagram showing a structure of a battery charging and discharging apparatus, according to an embodiment of the present disclosure;

FIG. 3 is a view showing an equivalent circuit of a single battery cell;

FIG. 4 is a view showing an equivalent circuit of a battery module or a battery pack;

FIG. 5 is a view showing a waveform of an alternating current (AC) impedance of a battery module;

FIG. 6 is a view showing a battery charging and discharging method, according to an embodiment disclosed herein; and

FIG. 7 is a view showing a hardware configuration of a battery charging and discharging apparatus, according to an embodiment disclosed herein.

### DETAILED DESCRIPTION OF THE INVENTION

Hereinafter, various embodiments disclosed herein will be described in detail with reference to the accompanying drawings. In this document, identical reference numerals will be used for identical components in the drawings, and the identical components will not be redundantly described.

For various embodiments disclosed herein, specific structural or functional descriptions are only exemplified for the purpose of describing the embodiments, and various embodiments disclosed herein may be implemented in various forms, and should not be construed as being limited to the embodiments described herein.

As used in various embodiments, the terms “1^{st}, 2^{nd}” “first”, “second”, or the like may modify various components regardless of importance, and do not limit the components. For example, a first component may be named as a second component without departing from the right scope of an embodiment disclosed herein, and similarly, the second component may be named as the first component.

Terms used herein are used for only describing a specific exemplary embodiment and may not have an intention to limit the scope of other exemplary embodiments. It is to be understood that the singular forms include plural references unless the context clearly dictates otherwise.

All terms including technical or scientific terms used herein have the same meaning as commonly understood by those of ordinary skill in the art to which the embodiments disclosed herein belong. It will be further understood that terms, such as those defined in commonly used dictionaries, should be interpreted as having a meaning that is identical to or similar with their meaning in the context of the relevant art and will not be interpreted in an idealized or overly formal sense unless expressly so defined herein. In some cases, the terms defined herein may be interpreted to exclude embodiments disclosed herein.

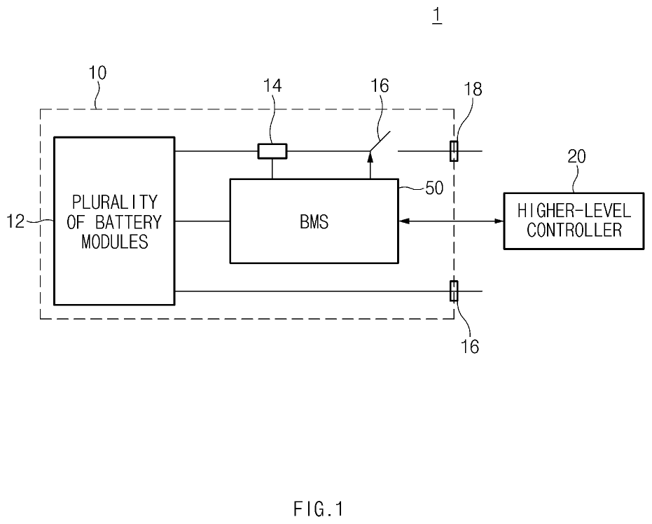

FIG. 1 is a block diagram showing a structure of a general battery pack.

More specifically, FIG. 1 schematically shows a battery control system 1 including a battery pack 10 and a higher-level controller 20 included in a higher-level system, according to an embodiment disclosed herein.

As shown in FIG. 1, the battery pack 10 may include a plurality of battery modules 12, a sensor 14, a switching unit 16, a connecting terminal 18, and a battery management system (BMS) 50. In this case, the battery pack 10 may include the battery module 12, the sensor 14, the switching unit 16, the connecting terminal 18, and the BMS 50, provided in plural.

The plurality of battery modules 12 may include at least one chargeable/dischargeable battery cells.

The sensor 14 may detect current flowing in the battery pack 10. In this case, a detection signal may be delivered to the BMS 50.

The switching unit 16 may be serially connected to a positive (+) terminal side or a negative (−) terminal side of the battery module 12 to control a charging/discharging current flow of the battery module 12. For example, for the switching unit 16, at least one relay, a magnetic contactor, etc., may be used, depending on the specification of the battery pack 10.

The connecting terminal 18 may connect the battery pack 10 to an outside. For example, a cable of a battery charging and discharging apparatus disclosed herein may be connected to the connecting terminal 18.

The BMS 50 may perform control and management to prevent over-charging and over-discharging by monitoring voltage, current, temperature, etc., of the battery rack 10, and may include, for example, a rack battery management system (RBMS).

The BMS 50 may include, as an interface for receiving a measurement value of various parameters described above, a plurality of terminals, a circuit connected to these terminals to perform processing of input values, etc. Further, the BMS 50 may control the switching unit 16, for example, on/off of a relay, a contactor, etc., and may be connected to the battery module 12 to monitor a state of each battery module 12.

Meanwhile, the battery charging and discharging apparatus disclosed herein may be connected to the connecting terminal 18 of the battery pack 10 to bring power from the battery module 12 or supply power to the battery module 12, thereby charging or discharging the battery module 12. At this time, the connecting terminal 18 may be a high voltage (HV) cable of the battery pack 10.

The higher-level controller 20 may transmit a control signal for controlling the battery module 12 to the BMS 50. Thus, the BMS 50 may be controlled in terms of an operation thereof based on the control signal applied from the higher-level controller 20.

Meanwhile, it is described with reference to FIG. 1 that the battery module 12 is included in the battery pack 10, the battery module 12 disclosed herein may be included in an energy storage system (ESS), without being limited thereto. In this case, the higher-level controller 20 may be a controller (a bank battery management system (BBMS)) of a battery bank including the plurality of battery packs 10 or an ESS controller for controlling the entire ESS including a plurality of banks. However, the battery pack 10 is not limited to such a purpose.

Such a structure of the battery pack 10 and a structure of the BMS 50 are well known, and thus a more detailed description thereof will be omitted.

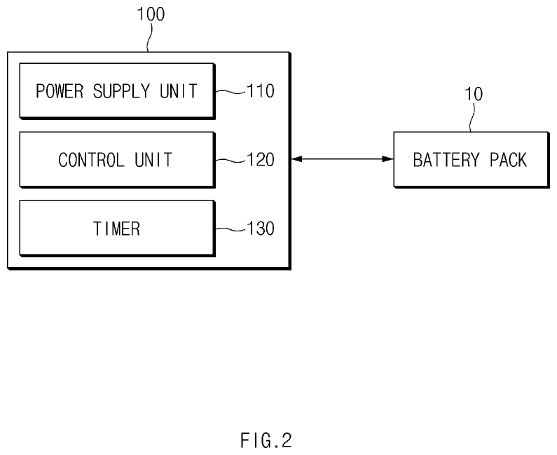

FIG. 2 is a block diagram showing a structure of a battery charging and discharging apparatus, according to an embodiment disclosed herein.

Referring to FIG. 2, a battery charging and discharging apparatus 100 according to an embodiment disclosed herein may be a portable battery charging and discharging apparatus connected to a battery to activate the battery for measurement of an alternating current (AC) impedance. As such, the battery charging and discharging apparatus 100 according to an embodiment disclosed herein may not need to use a chamber as conventionally, because of mainly performing a low-rate charging and discharging.

As shown in FIG. 2, the battery charging and discharging apparatus 100 according to an embodiment disclosed herein may include a power supply unit 110 (i.e., power supply), a control unit 120 (i.e., controller), and a timer 130.

The power supply unit 110 may supply power to the battery pack 10. For example, the power supply unit 110 may be a small-size battery included in the battery charging and discharging apparatus 100 to store a power. In addition, the power supply unit 110 may store the power discharged from the battery pack 10 for a predetermined time.

The control unit 120 may discharge the battery to store power in the power supply unit 110, and continuously supply the power stored in the power supply unit 110 to the battery to charge the battery. In this case, the control unit 120 may make a state of charge (SOC) of the battery into a user-set value by charging and discharging the battery. In addition, the control unit 120 may automatically discharge the battery at a preset time and then recharge the battery. At this time, the time at which the control unit 120 charges the battery may be set by the timer 130.

Further, in order to charge and discharge the battery, the preset time may be determined in consideration of a time at which the battery enters a rest period. Therefore, it is possible to enable the battery to enter the rest period at a desired time by activating the battery through charging and discharging of the battery in time for a user to measure a (high-voltage) AC impedance. Thus, the user may measure the high-voltage AC impedance (electrochemical impedance spectroscopy (EIS)) at a desired time.

The control unit 120 may charge the battery such that a voltage of the battery reaches a reference voltage. In this case, the reference voltage may be set to a voltage (e.g., 40V) allowing measurement of the AC impedance of the battery. Typically, to measure the AC impedance of the battery, a voltage should be greater than or equal to a certain reference is required. Thus, the control unit 120 may discharge the battery to cause the voltage to fall, and then control the battery such that the voltage is greater than or equal to a constant voltage during recharging, thereby enabling the user to measure the AC impedance.

Moreover, the power for charging and discharging the battery through the control unit 120 may have a value greater than or equal to a threshold value in which a chemical reaction may be initiated in the battery. Therefore, the chemical reaction inside the battery may be initiated by the power charged and discharged by the control unit 120, such that the battery may be activated to enable measurement of the AC impedance of the battery.

The timer 130 may set a time to charge and discharge the battery at a preset time. That is, when the user makes an input to set a time through an input unit, the timer 130 may transmit a signal for charging and discharging the battery according to the set time to the control unit 120. Thus, the battery may be activated at a user-desired time, e.g., in time to measure the AC impedance.

On the other hand, the battery charging and discharging apparatus according to one embodiment disclosed herein may include a converter, as known in the art. Thus, when the voltage of the battery pack and the voltage of the battery charging and discharging apparatus do not match, they may be adjusted to each other through the converter.

The battery charging and discharging apparatus 100 according to an embodiment disclosed herein may be connected to a terminal of the battery pack 10 via the cable. In this case, the battery charging and discharging apparatus 100 may be connected to an HV cable terminal of the battery pack 10.

In addition, a size of the battery charging and discharging apparatus 100 according to an embodiment disclosed herein may be determined depending on current magnitude and capacity of the battery. That is, depending on whether a battery to be measured in terms of an AC impedance is a pack or a module, the size may be a size of a vacuum cleaner holdable by one hand, or may be a size of a living room vacuum cleaner that operates wiredly.

As such, with the battery charging and discharging apparatus according to the present disclosure, by activating the battery using the portable charging and discharging apparatus, the rest period for measuring the AC impedance of the battery may be easily managed and the volume of the apparatus may be reduced.

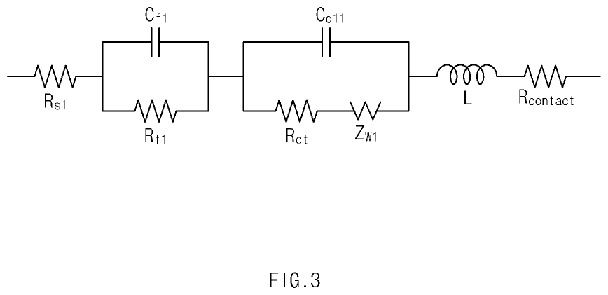

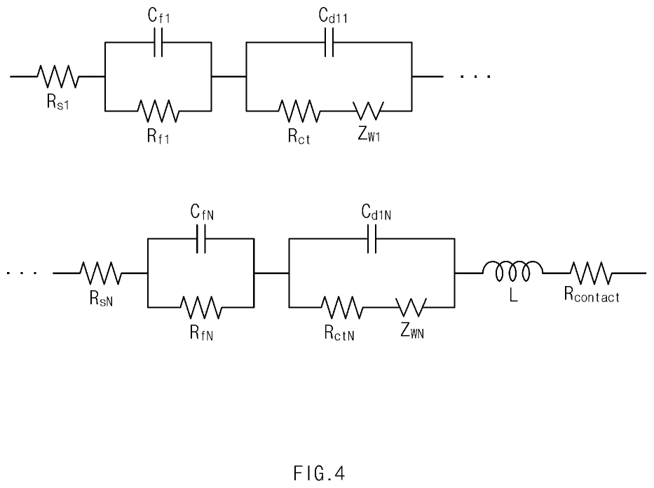

FIG. 3 is a view showing an equivalent circuit of a single battery cell, and FIG. 4 is a view showing an equivalent circuit of a battery module or a battery pack.

First, a battery charging and discharging apparatus according to an embodiment of the present disclosure may apply an AC to a battery module or a battery pack in a specific frequency range (e.g., 0.1 through several Hz) and measure a voltage response for each frequency band to measure a magnitude and a phase of an impedance. Moreover, each parameter value of the battery may be extracted based on reactions of respective parameters of an equivalent circuit of a battery cell/module/pack with respect to a frequency.

In particular, a high-voltage AC impedance analysis method based on the battery charging and discharging apparatus according to the present disclosure measures a battery module or a battery pack where a plurality of normal battery cells and at least one abnormal battery cells are connected, in which the type of a result value to be extracted and the number of result values may differ, due to a difference in equivalent circuit than in the existing EIS measurement method.

Thus, referring to FIG. 3, first, for an existing scheme to measure EIS of a single battery cell, a voltage range is around 20V and a frequency range is from 0.1 to 1050 Hz. In addition, an anode and a cathode may be separately measured in a three-electrode measurement manner, and an ohmic resistance may be corrected through noise cancellation. The equivalent circuit of FIG. 3 comprises Rₛₗ ohmic resistance, R_{fl} SEI resistance, C_{fl} SEI capacitance, R_{ct} charge transfer capacitance, C_{dll} double layer capacitance, Z_{wl} Warburg impedance, L inductance, and R_{contact} parasitic resistance. The equivalent circuit of FIG. 3 may be based on the Randles equivalent circuit model.

Such a conventional measurement scheme may perform measurement in a steady state of the battery cell, i.e., in a state of chemical equilibrium and anode-potential equilibrium, and detect abnormality through absolute comparison of the battery cell with a reference value. As such, the existing cell-unit EIS measurement method should decompose the battery module or the battery pack into cell units, and has difficulty in three-electrode measurement and formation of a chemical equilibrium state, having a limitation in application to an actual product.

On the other hand, in a high-voltage AC impedance measurement method according to the present disclosure using an equivalent circuit in the unit of a battery module including a plurality of battery cells or a battery pack as shown in FIG. 4, a voltage range is around 1000V and a frequency range is from 0.1 to 4000 Hz. Further, by using a two-electrode measurement scheme for a plurality of battery cells that are serially connected, repeated and reproduced measurement are possible. Moreover, with this scheme, a parasitic resistance caused by a contactor, a wire, etc., may be corrected and an influence of the parasitic resistance may be minimized by serial connection of the plurality of battery cells. The equivalent circuit of FIG. 4 comprises R_{SN} Nₜₕ ohmic resistance, R_{fN} Nₜₕ SEI resistance, C_{fN} Nₜₕ SEI capacitance, R_{ctN} Nₜₕ charge transfer capacitance, C_{dllN} Nₜₕ double layer capacitance, Z_{wN} Nₜₕ Warburg impedance, L inductance, and R_{contact} parasitic resistance. The equivalent circuit of FIG. 4 may be based on the Randles equivalent circuit model.

The high-voltage AC impedance measurement method used in the battery charging and discharging apparatus according to an embodiment disclosed herein may perform measurement in a state after charging and discharging of all battery modules of the same battery rack are finished at the same time, and may be capable of both relative comparison and absolute comparison for each battery module. In particular, with this scheme, an impedance value of a battery system may increase in proportion to the number of serial connections of the battery cells, N, according to the equivalent circuit shown in FIG. 4, such that when a Nyquist plot is obtained from measurement data and analysis is performed, an external influence (e.g., a sensing line inductance, a contact resistance, etc.) with respect to a measurement condition may be reduced in comparison to the single battery cell.

As such, according to the high-voltage AC impedance measurement method used in the battery charging and discharging apparatus according to an embodiment disclosed herein, measurement and abnormality diagnosis may be performed without decomposition into battery cell units, and the immediate reuse of the battery is possible and thus the battery may be directly applied to a battery module or rack of an ESS or a vehicle battery pack. In addition, it is not necessary to charge and discharge the battery, thereby reducing the power due to charging and discharge.

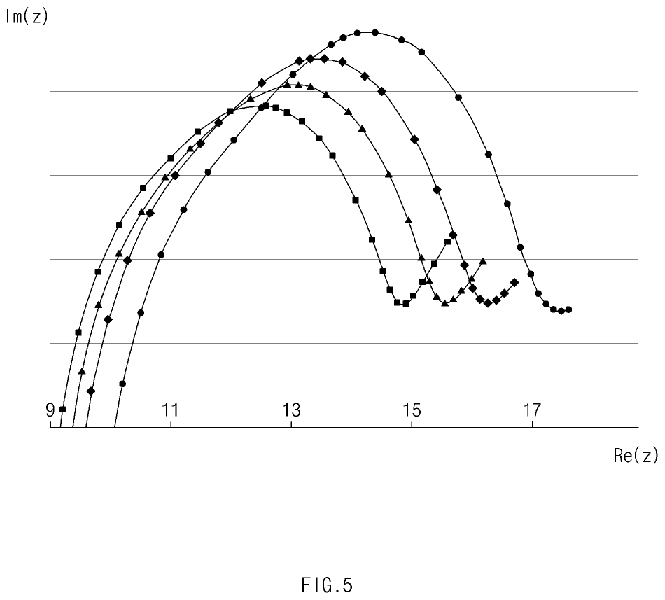

FIG. 5 is a view showing a waveform of an AC impedance of a battery module. In a graph of FIG. 5, an x-axis indicates a resistance element (real(Z)) mOhm of an AC impedance, and a y-axis indicates a reactance element (imaginary(Z)) mOhm of an AC impedance.

Referring to FIG. 5, a high-voltage AC impedance value of each battery module measured at certain intervals is shown. In this case, it may be seen that the shape of an AC impedance waveform of the battery module differs with the battery module. Thus, in a BMS, the degree of aging of the battery module may be estimated in a manner like a case where a measured AC impedance of a particular battery module is greatly different from that of another battery module or deviates from a reference range set based on an AC impedance of an aged battery module established in advance in a database. To this end, the battery charging and discharging apparatus according to an embodiment disclosed herein may previously activating the battery to obtain the waveform of the (high-voltage) AC impedance as shown in FIG. 5, thereby causing the battery to be in a measurement-possible state.

In this manner, for the battery module, which has been aged much, a remaining life may be identified through a separate charging and discharging test, and may be used as reference data in later abnormality detection of the battery module. For example, the remaining life of a replaced battery module and the measured AC impedance value may be matched and stored in the form of a table, thus being used as reference data in later abnormality diagnosis for the battery module. Meanwhile, when the aged battery module is replaced, the reusable battery may be used to replace the battery at an affordable price and the system may be stably operated by adjusting the degree of aging of the entire battery system of the ESS.

As such, the battery charging and discharging apparatus according to an embodiment disclosed herein may be used to cause the rest period to fall within a desired time range by previously activating the battery, so as to diagnose the degree of aging by measuring the AC impedance of the battery. In particular, the battery charging and discharging apparatus according to the present disclosure are mainly intended for battery activation and reference voltage check, and thus needs only a capacity for temporarily storing a power supplied from the battery pack and supplying the same again to the battery pack, thus being portable with a small volume.

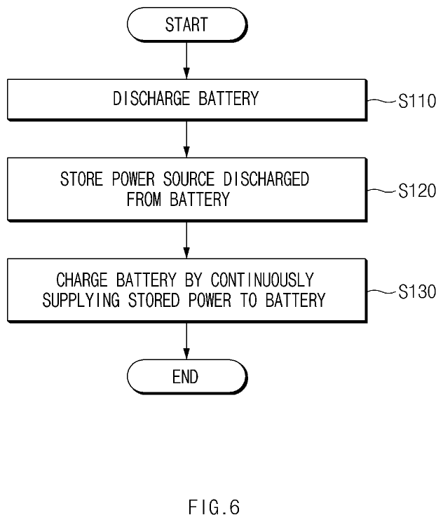

FIG. 6 is a view showing a battery charging and discharging method, according to an embodiment disclosed herein.

A battery charging and discharging method according to an embodiment disclosed herein, which is shown in FIG. 6, may be a battery charging and discharging method using a portable battery charging and discharging apparatus connected to a battery to activate the battery for AC impedance measurement.

According to the battery charging and discharging method according to an embodiment disclosed herein, first, the battery may be discharged in operation S110. Next, a power discharged from the battery is stored in operation S120. In this case, the power from the battery pack may be stored in a power supply unit (e.g., the battery) included in the battery charging and discharging apparatus.

Next, the stored power is continuously supplied to the battery to charge the battery, in operation S130. In this case, in operation S110 through S130, the battery may be automatically discharged at a preset time and then recharged. In particular, the preset time for charging and discharging the battery may be determined in consideration of a time at which the battery enters the rest period. Therefore, it is possible to enable the battery to enter the rest period at a desired time by activating the battery through charging and discharging of the battery in time for a user to measure a (high-voltage) AC impedance.

In operation S130, the battery may be charged such that the voltage of the battery reaches a reference voltage. In this case, the reference voltage may be set to a voltage (e.g., 40V) allowing measurement of the AC impedance of the battery. Typically, to measure the AC impedance of the battery, a voltage should be greater than or equal to a certain reference is required. Thus, in operation S130, the battery may be discharged to cause the voltage to fall, and then the battery may be controlled such that the voltage is greater than or equal to a constant voltage during recharging, thereby enabling the user to measure the AC impedance.

Further, the power for charging and discharging the battery may have a value greater than or equal to a threshold value in which a chemical reaction may be initiated in the battery. Therefore, the chemical reaction in the battery may be initiated by the charged and discharged power and thus the battery may be activated to enable measurement of the AC impedance of the battery.

As such, with the battery charging and discharging method according to the present disclosure, by activating the battery using the portable charging and discharging apparatus, the rest period for measuring the AC impedance of the battery may be easily managed and the volume of the apparatus may be reduced.

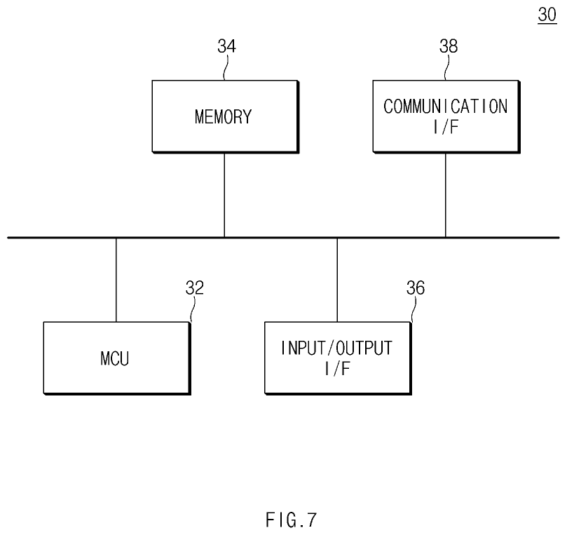

FIG. 7 is a block diagram showing a computing system that performs a battery management method according to an embodiment disclosed herein.

Referring to FIG. 7, a computing system 30 according to an embodiment disclosed herein may include a microcontroller unit (MCU) 32, a memory 34, an input/output interface (I/F) 36, and a communication I/F 38.

The MCU 32 may be a processor that executes various programs (e.g., a battery charging and discharging control program, etc.) stored in the memory 34, processes various data for charging and discharging of a battery pack through these programs, and executes the above-described functions of the control unit 120 or the timer 130 of the battery charging and discharging apparatus shown in FIG. 2.

The memory 34 may store various programs for controlling charging and discharging of the battery pack. The memory 720 may store various data such as data regarding a charging and discharging power of the battery pack.

The memory 34 may be provided in plural, depending on a need. The memory 34 may be a volatile or nonvolatile memory. For the memory 34 as the volatile memory, random access memory (RAM), dynamic RAM (DRAM), static RAM (SRAM), etc., may be used. For the memory 34 as the nonvolatile memory, read only memory (ROM), programmable ROM (PROM), electrically alterable ROM (EAROM), erasable PROM (EPROM), electrically erasable PROM (EEPROM), flash memory, etc., may be used. The above-listed examples of the memory 34 are merely examples and are not limited thereto.

The input/output I/F 36 may provide an interface for transmitting and receiving data by connecting an input device such as a keyboard, a mouse, a touch panel, etc., and an output device such as a display, etc., with the MCU 32.

The communication I/F 340, which is a component capable of transmitting and receiving various data to and from a server, may be various types of devices capable of supporting wired or wireless communication. For example, a program for controlling charging and discharging of the battery pack or various data, etc., may be transmitted and received to and from a separately provided external server through the communication I/F 38.

As such, a computer program according to an embodiment disclosed herein may be recorded in the memory 34 and processed by the MCU 32, thus being implemented as a module that performs functions shown in FIG. 2.

The battery charging and discharging apparatus and method according to an embodiment disclosed herein may easily manage the rest period for AC impedance measurement of the battery and reduce the volume of the apparatus, by activating the battery using the portable charging and discharging apparatus.

Even though all components constituting an embodiment disclosed herein have been described above as being combined into one or operating in combination, the embodiments disclosed herein are not necessarily limited to the embodiment. That is, within the object scope of the embodiments disclosed herein, all the components may operate by being selectively combined into one or more.

Moreover, terms such as “include”, “constitute” or “have” described above may mean that the corresponding component may be inherent unless otherwise stated, and thus should be construed as further including other components rather than excluding other components. All terms including technical or scientific terms have the same meanings as those generally understood by those of ordinary skill in the art to which the embodiments disclosed herein pertain, unless defined otherwise. The terms used generally like terms defined in dictionaries should be interpreted as having meanings that are the same as the contextual meanings of the relevant technology and should not be interpreted as having ideal or excessively formal meanings unless they are clearly defined in this document.

The above description is merely illustrative of the technical idea disclosed herein, and various modifications and variations will be possible without departing from the essential characteristics of the embodiments disclosed herein by those of ordinary skill in the art to which the embodiments disclosed herein pertain. Therefore, the embodiments disclosed herein are intended for description rather than limitation of the technical spirit of the embodiments disclosed herein and the scope of the technical spirit disclosed herein is not limited by these embodiments. The protection scope of the technical spirit disclosed herein should be interpreted by the following claims, and all technical spirits within the same range should be understood to be included in the range of this document.

### DESCRIPTION OF REFERENCE NUMERALS

1: BATTERY CONTROL SYSTEM
10: BATTERY PACK
12: PLURALITY OF BATTERY MODULES
14: SENSOR
16: SWITCHING UNIT
18: CONNECTING TERMINAL
20: HIGHER-LEVEL CONTROLLER
30: COMPUTING SYSTEM
32: MCU
34: MEMORY
36: INPUT/OUTPUT I/F
38: COMMUNICATION I/F
50: BATTERY MANAGEMENT SYSTEM(BMS)
100: BATTERY CHARGING AND DISCHARGING APPARATUS
110: POWER SUPPLY UNIT
120: CONTROL UNIT
130: TIMER

What is claimed is:

1. A portable battery charging and discharging apparatus connected to a battery to activate the battery, the battery charging and discharging apparatus comprising:
a power supply storing power discharged from the battery and supplying the power to the battery; and
a controller storing the power in the power supply by discharging the battery and charging the battery by continuously supplying the power stored in the power supply to the battery.

2. The battery charging and discharging apparatus of claim 1, wherein the controller automatically discharges the battery at a preset time and recharges the battery.

3. The battery charging and discharging apparatus of claim 2, wherein the preset time is determined in consideration of a time at which the battery enters a rest period.

4. The battery charging and discharging apparatus of claim 1, wherein the controller charges the battery such that a voltage of the battery reaches a reference voltage.

5. The battery charging and discharging apparatus of claim 4, wherein the reference voltage is set to a voltage that enables alternating current (AC) impedance measurement of the battery.

6. The battery charging and discharging apparatus of claim 1, wherein a size of the battery charging and discharging apparatus is determined according to a current magnitude and a capacity of the battery.

7. The battery charging and discharging apparatus of claim 1, wherein a power for charging and discharging the battery has a value greater than or equal to a threshold value that enables a chemical reaction to be initiated in the battery.

8. The battery charging and discharging apparatus of claim 1, wherein the battery charging and discharging apparatus is connected to a terminal of the battery through a cable.

9. A battery charging and discharging method using a portable battery charging and discharging apparatus connected to a battery to activate the battery, the battery charging and discharging method comprising:
discharging the battery;
storing a power discharged from the battery; and
charging the battery by continuously supplying the stored power to the battery.

10. The battery charging and discharging method of claim 9, wherein the discharging of the battery comprises automatically discharging the battery at a preset time.

11. The battery charging and discharging method of claim 10, wherein the preset time is determined in consideration of a time at which the battery enters a rest period.
